(19) United States
(12) Patent Application Publication
(10) Pub. No.: US 2009/0282318 A1
(43) Pub. Date: Nov. 12, 2009

(54) SEMICONDUCTOR MEMORY DEVICE

(75) Inventors: Katsuhiko HOYA, Yokohama-shi (JP); Shinichiro SHIRATAKE, Yokohama-shi (JP)

Correspondence Address: KNOBBE MARTENS OLSON & BEAR LLP, 2040 MAIN STREET, FOURTEENTH FLOOR, IRVINE, CA, 92614, US

(73) Assignee: KABUSHIKI KAISHA TOSHIBA, Tokyo (JP)

(21) Appl. No.: 12/410,192

(22) Filed: Mar. 24, 2009

(30) Foreign Application Priority Data
May 7, 2008 (JP) 2008-121013

(51) Int. Cl. G06F 11/10; G11C 11/22; G11C 11/24; G11C 8/18

(52) U.S. Cl. 714/773; 365/145; 365/149; 365/233.1; 714/E11.036

(57) ABSTRACT

A semiconductor memory device according to an aspect of the present invention includes a memory cell array that includes a ferroelectric capacitor and a selection transistor that selects a column of the memory cell array and connects the selected column to a bit line. A plate line applies a potential for reading or writing data to the ferroelectric capacitor. A sense amplifier circuit compares and amplifies a signal read from the ferroelectric capacitor to the bit line. A plate line control circuit controls a potential of the plate line synchronously with a clock signal.

### CROSS REFERENCE TO RELATED APPLICATIONS

This application is based on and claims the benefit of priority from prior Japanese Patent Application No. 2008-121013, filed on May 7, 2008, the entire contents of which are incorporated herein by reference.

### BACKGROUND OF THE INVENTION

1. Field of the Invention

The present invention relates to a semiconductor memory device and particularly relates to a structure of a ferroelectric memory and an operating method therefor.

2. Description of the Related Art

There is conventionally known a ferroelectric memory as one type of nonvolatile memories. The ferroelectric memory is a memory that can store binary data in a nonvolatile fashion according to two different polarization magnitudes of a ferroelectric material, based on one of characteristics of the ferroelectric material that spontaneous polarization has a hysteresis characteristic. Memory cells of a conventional ferroelectric memory are generally similar in architecture to a DRAM. A paraelectric capacitor is replaced by a ferroelectric capacitor and the ferroelectric capacitor is connected to a transistor in series. By arranging a plurality of pairs of the paraelectric capacitor and the transistor, a memory cell array is constituted.

Since data is read from the ferroelectric memory by applying a voltage to the corresponding ferroelectric capacitor to cause polarization reversal of the ferroelectric capacitor, a read operation performed by the ferroelectric memory is destructive readout. Therefore, after the data is read, it is necessary to rewrite the read data in such a ferroelectric memory as a FeRAM. By holding a state resulting from comparison and amplification made by a sense amplifier, data “0” can be rewritten. Thereafter, a potential of a plate line is returned to VSS (ground potential), whereby data “1” can be rewritten to the memory cell (refer to, for example, Japanese Patent Application Laid-Open No. 2001-250376).

Conventionally, in a burst mode in which data is continuously read and written, the potential of the plate line PL is held in an “H” state for a long time and data “0” is rewritten, the potential of the plate line PL is set into an “L” state at the end of an operation cycle and data “1” is rewritten. Thus, data “0” rewrite time is longer than data “1” rewrite time and an imbalance between the data “0” rewrite time and the data “1” rewrite time occurs. Defects such as an imprint resulting from this imbalance occurs to the ferroelectric capacitor, disadvantageously resulting in deterioration of data reliability.

Meanwhile, an ECC (Error Correction and Checking) circuit is a circuit that functions to correct error bits included in a plurality of pieces of data read from a memory. If error data is read at a certain probability, the ECC circuit can correct errors and output corrected data. Therefore, by incorporating the ECC circuit in the memory, it is possible to improve data reliability of the memory to some extent.

Nevertheless, to write back corrected data to the memory cell, it is required to hold the plate line PL in an “H” state and to maintain a data “0” rewrite state until the ECC calculation ends and the corrected data is reflected in the bit lines. Accordingly, data “0” rewrite time is longer than data “1” rewrite time and an imbalance still occurs between the data “1” rewrite time and the data “1” rewrite time. As a result, defects such as imprint occur to a ferroelectric capacitor and data reliability of the memory deteriorates.

### SUMMARY OF THE INVENTION

According to one aspect of the present invention, there is provided a semiconductor memory device including: a memory cell array including a ferroelectric capacitor; a selection transistor selecting a column of the memory cell array and connecting the selected column to a bit line; a plate line applying a potential for reading or writing data from or to the ferroelectric capacitor; a sense amplifier circuit comparing and amplifying a signal read from the ferroelectric capacitor to the bit line; and a plate line control circuit controlling a potential of the plate line synchronously with a clock signal.

### BRIEF DESCRIPTION OF THE DRAWINGS

FIG. 1 is a block diagram of a ferroelectric memory according to a first embodiment of the present invention;

FIG. 2 shows a configuration of a part of a memory cell array of the ferroelectric memory according to the first embodiment of the present invention;

FIG. 3 is a block diagram of a plate line control circuit according to the first embodiment of the present invention;

FIG. 4 is an operation timing chart of the plate line control circuit according to the first embodiment of the present invention;

FIG. 5A shows a hysteresis characteristic of the ferroelectric memory and FIG. 5B shows a structure of a ferroelectric memory cell;

FIG. 6 is an operation timing chart of the ferroelectric memory according to the first embodiment of the present invention;

FIG. 7 shows a circuit configuration of a register of the ferroelectric memory according to the first embodiment of the present invention;

FIG. 8 is an operation timing chart of a ferroelectric memory according to a second embodiment of the present invention;

FIG. 9 is an operation timing chart of a ferroelectric memory according to a third embodiment of the present invention;

FIG. 10 is an operation timing chart of a ferroelectric memory according to a fourth embodiment of the present invention;

FIG. 11 is an operation timing chart of a ferroelectric memory according to a fifth embodiment of the present invention; and

FIG. 12 is an operation timing chart of a conventional ferroelectric memory.

### DETAILED DESCRIPTION OF THE EMBODIMENTS

Embodiments of a semiconductor memory according to the present invention will be described hereinafter in detail with reference to the accompanying drawings.

### First Embodiment

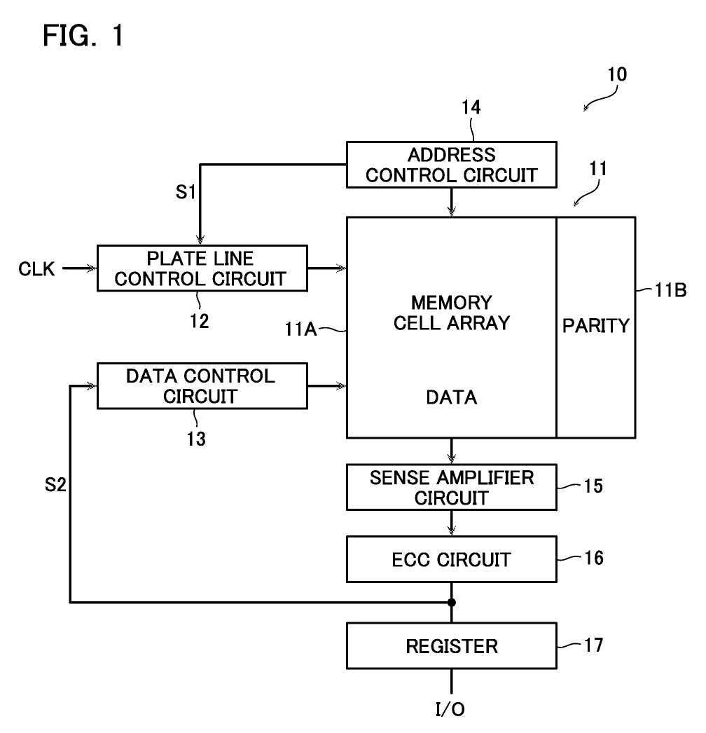

FIG. 1 is a block diagram showing a configuration of a ferroelectric memory according to a first embodiment of the present invention. The ferroelectric memory 10 includes a memory cell array 11 configured by arranging a plurality of memory cells.

The memory cell array 11 includes a data storage area 11A and a parity storage area 11B. A plate line control circuit 12 for controlling a potential of a plate line PL connected to a selected memory cell, a data control circuit 13 for controlling a potential of a bit line BL connected to the selected memory cell, an address control circuit 14 for selecting a desired memory cell and a sense amplifier circuit 15 for comparing and amplifying signals on the bit line BL is connected to the memory cell array 11.

The plate line control circuit 12 receives a plate line selection signal S1 from the address control circuit 14 and a clock signal CLK, and controls a potential of a predetermined plate line PL connected to a selected memory cell. An ECC circuit 16 for error correction is connected to the sense amplifier circuit 15 and a correction data signal S2 from the ECC circuit 16 is input to the data control circuit 13. A data signal amplified by the sense amplifier circuit 15 is output from the sense amplifier circuit 15 to an I/O terminal via a register 17.

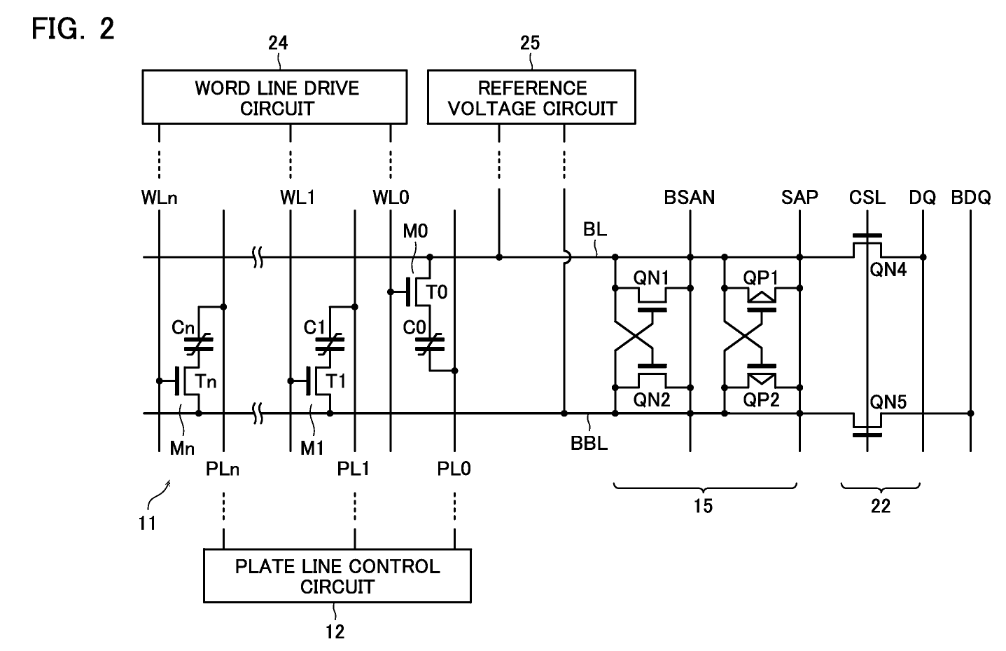

A configuration of the memory cell array 11 will first be described in detail. FIG. 2 schematically shows one column of the memory cell array 11. While a memory cell Mi (i=0 to n) shown in FIG. 2 is a 1T/1C memory cell constituted by one transistor (such as an NMOS transistor) Ti and one ferroelectric capacitor Ci, the memory cell is not limited thereto. A drain electrode of the transistor Ti is connected to one of electrodes of the ferroelectric capacitor Ci. A gate of the transistor Ti is connected to a word line WLi and the other electrode of the ferroelectric capacitor Ci is connected to a plate line PLi. The word line WLi is connected to a word line drive circuit 24 that is a part of the address control circuit 14 and driven by the word line drive circuit 24. The plate line PLi is driven by the plate line control circuit 12 as will be described later in detail. A plurality of memory cells Mi is arranged between each pair of bit lines and a plurality of bit lines is arranged in parallel, thereby constituting the memory cell array 11.

Between bit lines BL and BBL constituting a pair of bit lines (also referred to as “paired bit lines”) connected to one sense amplifier circuit 15, the sense amplifier 15 and a column gate 22 are connected in parallel outside of the memory cell array 11 in this order seen from the memory cell array 11. Furthermore, a reference voltage circuit 25 for applying a reference voltage Vref to one of the paired bit lines BL and BBL is provided.

The sense amplifier circuit 15 includes, for example, an NMOS flip-flop circuit constituted by NMOS transistors QN1 and QN2 and a PMOS flip-flop circuit constituted by PMOS transistors QP1 and QP2. A terminal of the NMOS flip-flop circuit is connected to a sense amplifier activation signal line BSAN and a terminal of the PMOS flip-flop circuit is connected to a sense amplifier activation signal line SAP.

The column gate 22 is connected between the paired bit lines BL and BBL to be adjacent to the sense amplifier circuit 15. The column gate 22 includes an NMOS transistor QN4 having a source electrode connected to the bit line BL and a drain electrode connected to a data line DQ and an NMOS transistor QN5 having a source electrode connected to the bit line BBL and a drain electrode connected to a data line BDQ. A gate of each of the transistors QN4 and QN5 is connected to a column selection line CSL and driven by the address control circuit 14.

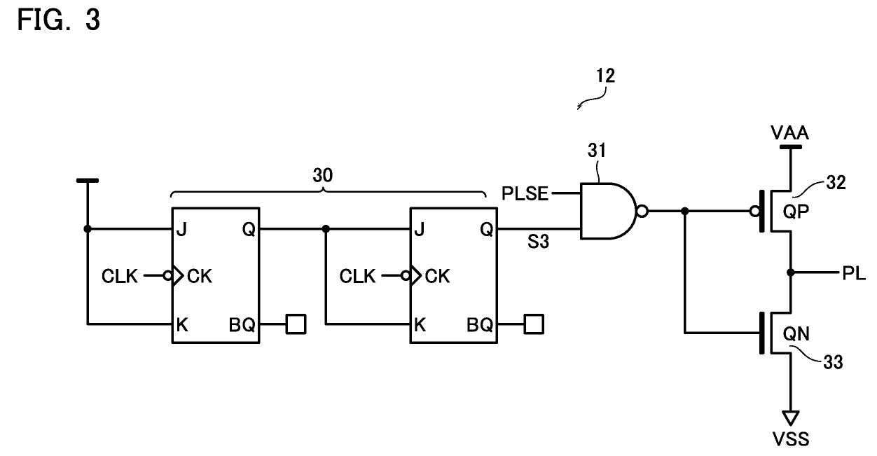

The plate line control circuit 12 will next be described in detail. FIG. 3 shows an example of a circuit configuration of the plate line control circuit 12. However, the circuit configuration of the plate line control circuit 12 is not limited to that shown in FIG. 3. The plate line control circuit 12 outputs a plate line signal PL in response to a plate line activation signal PLSE from the address control circuit 14 in synchronization with an external clock signal CLK. The plate line control circuit 12 includes a one-quarter frequency divider circuit 30, a NAND gate 31, a PMOS transistor 32 and an NMOS transistor 33 having a drain electrode connected to a drain electrode of the PMOS transistor 32. A plate line PL is connected to a connection node at which the PMOS transistor 32 is connected to the NMOS transistor 33. A voltage of a source electrode of the PMOS transistor is kept equal to a voltage VAA (an internal power supply voltage) whereas a source side of the NMOS transistor is kept equal to a ground potential VSS. An output terminal of the NAND gate 31 is connected to gates of the PMOS transistor 32 and the NMOS transistor 33, respectively. An output terminal of the one-quarter frequency divider circuit 30 is connected to one of the input terminals of the NAND gate 31. Although the one-quarter frequency divider circuit 30 is employed in the example shown in FIG. 3, needless to say, a frequency dividing rate can be changed according to the conditions. Furthermore, by adding a logic circuit such as a selector circuit, the potential of the plate line PL can be appropriately controlled to be changed over between “H” and “L”.

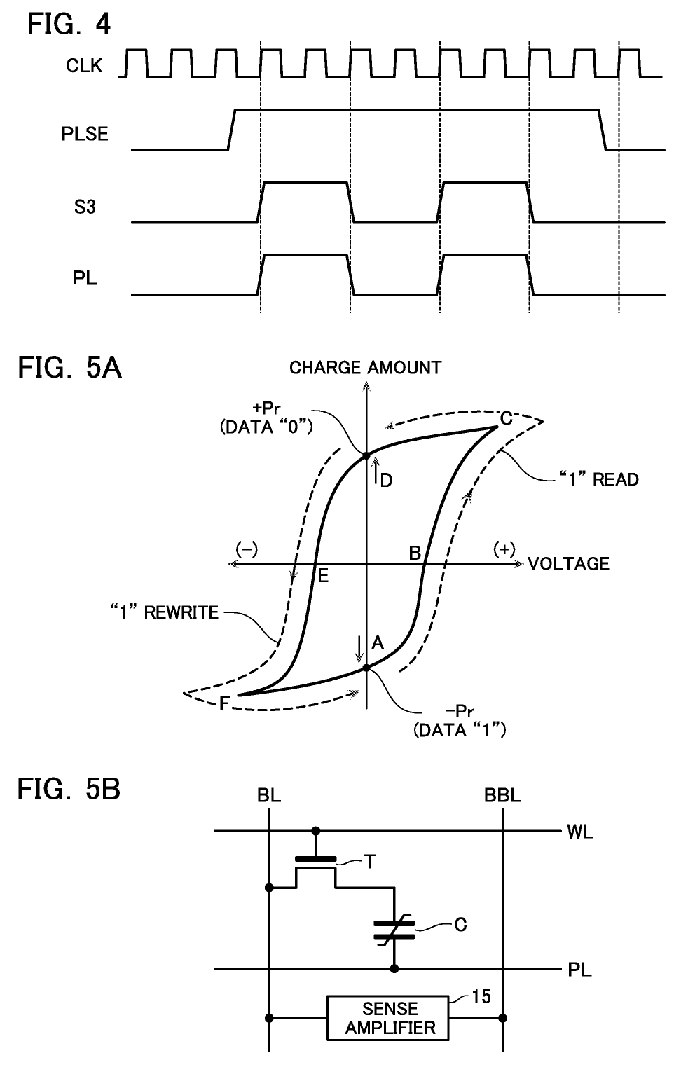

A circuit operation performed by the plate line control circuit 12 will next be described. FIG. 4 is an example of a timing chart of the plate line control circuit 12. The one-quarter frequency divider circuit 30 generates and outputs a signal S3 obtained by dividing a frequency of the input clock signal CLK by four. The signal S3 is input to one of input terminals of the NAND gate 31. The plate line activation signal PLSE (S1) from the address control circuit 14 is input to the other input terminal of the NAND gate 31. If the potential of the plate line activation signal PLSE is “H” and that of the signal S3 is “H”, a potential “L” is output from the NAND gate 31, then the NMOS transistor 33 is turned off, the PMOS transistor 32 is turned on and high potential VAA (“H”) is applied to the plate line PL. If the potential of the plate line activation signal PLSE is “H” and that of the signal S3 is “L”, a potential “H” is output from the NAND gate 31, then the PMOS transistor 32 is turned off, the NMOS transistor 33 is turned on and low potential VSS (“L”) is applied to the plate line PL.

As described above, in this plate line control circuit 12, the potential of the plate line PL is changed over between “H” and “L” in synchronization with the clock signal and an “H” time interval and an “L” time interval are set substantially equal to each other. “Substantially equal” means herein that the “H” time interval and the “L” time interval of the plate line PL become equal after a column corresponding to one pair of bit lines BL and BBL in the memory cell array 11 is selected. Preferably, at the start of an operation cycle before selection of a column, a potential of the plate line PL is set to “H” in advance by using a selector circuit or the like that is not shown before potentials of the paired bit lines BL and BBL reach predetermined potentials. After selection of the column, the potential of the plate line PL is switched over between “H” and “L” with the “H” time interval and the “L” time interval set equal to each other.

By doing so, if data is to be read and rewritten and the ECC circuit 16 makes error correction, it is possible to keep data “0” rewrite time and data “1” rewrite time in balance when data is read and rewritten in a burst mode. It is thereby possible to prevent an imprint and the like of the ferroelectric capacitor and improve data reliability.

The data control circuit 13 described above outputs data control signals for the memory cell array 11 including a chip activation signal bCE, a chip internal basic signal RINT, an ECC correction signal and the like in synchronization with the external clock signal CLK. The address control signal 14 described above outputs address control signals including a column selection signal CSLE for driving the transistors QN4 and QN5 of the column gate 22, a word line selection signal for driving the word line drive circuit 24, a signal for applying the reference voltage Vref to one of the bit lines of the selected column, the plate line activation signal PLSE applied to the plate line control circuit 12 and the like.

The ECC circuit 16 will next be described. The ECC circuit 16 includes a parity calculation circuit, a syndrome calculation circuit, a data correcting circuit and the like that are not shown. Data information used for calculation in the ECC circuit 16 is stored in the parity area 11B in the memory cell array 11 as a parity. The ECC circuit 16 compares data stored in the selected memory cell with the parity on the data, thereby detecting a data error and instructs the data control circuit 13 to invert potentials of the paired bit lines BL and BBL.

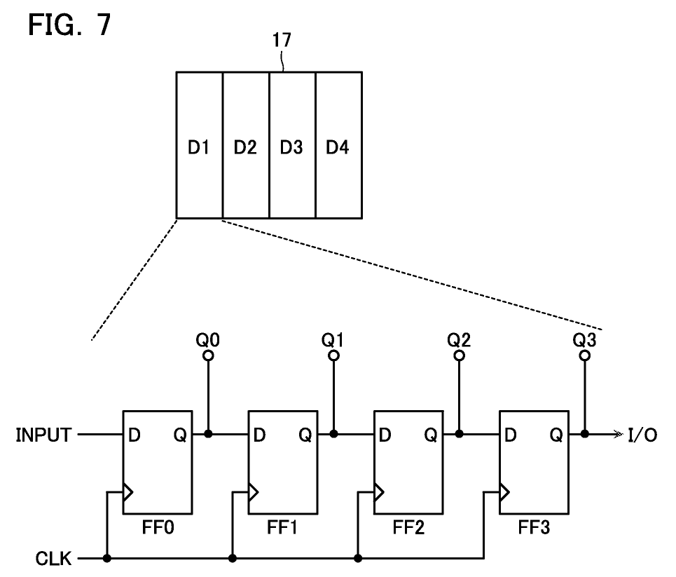

The register 17 will next be described. FIG. 7 schematically shows a circuit configuration of the register 17. The register 17 includes four divided register regions D1, D2, D3 and D4, each of which is a shift register including four flip-flop circuits FF0, FF1, FF2 and FF3 connected in series. However, the configuration of the register 17 is not limited to that shown in FIG. 7.

Next, basic operation performed by the ferroelectric memory will be described in detail with reference to the drawings.

FIG. 5A shows a hysteresis characteristic of the ferroelectric capacitor. As described above, the ferroelectric memory stores data in a nonvolatile fashion using the hysteresis characteristic of the ferroelectric capacitor. Out of two polarization states, an upward polarization state is made to correspond to “0” and a downward polarization state is made to correspond to “1”. Further, residual polarization amounts when a voltage applied to the ferroelectric capacitor is 0 V are +Pr and −Pr, respectively.

A read operation and a rewrite operation of the ferroelectric capacitor will be described taking a 1T/1C cell (a cell constituted by one transistor T and one ferroelectric capacitor C) shown in FIG. 5B as an example.

If data “1” (downward polarization amount −Pr) is held in the ferroelectric capacitor C, the potential of the bit line BL is set to 0 V, the word line WL is turned on and a voltage Vcc is applied to the plate line PL so as to read the data “1”. In this case, the hysteresis of the ferroelectric capacitor C follows a course of A→B→C and polarization of the ferroelectric capacitor C is reversed. Electric charges flow from the capacitor C via the transistor T to the bit line BL to charge up the bit line BL to a potential V1. At this time, the reference voltage Vref is applied to the other bit line BBL. If V1>Vref, the sense amplifier circuit 15 determines that the potential of the bit line BL is “H” and data “1” is output. Thereafter, when the word line WL is turned off, the ferroelectric capacitor C turns into a zero bias state and holds a data “0” state (charge amount+Pr, position D).

When data “1” is read from the memory cell, the data is destroyed due to the polarization reversal and the ferroelectric capacitor C turns into the data “0” Of state. Therefore, it is necessary to write the data “1” again and return the state of the ferroelectric capacitor C to the state before reading the data “1”. After reading the data “1”, the potential of the bit line BL is charged up. In this state, by setting the potential of the plate line PL to 0 V, a negative voltage is applied between electrodes of the ferroelectric capacitor C, the hysteresis of the ferroelectric capacitor C follows a course of D→E→F and the polarization of the ferroelectric capacitor C is reversed. As a result, data “1” is written again. Thereafter, when the word line WL is turned off, the ferroelectric capacitor C turns into a zero bias state and holds the data “1” (charge amount −Pr, position A). As a consequence, the state of the ferroelectric capacitor C returns to the original data “1” holding state.

On the other hand, when data “1” (downward polarization amount −Pr) is held in the ferroelectric capacitor C, the potential of the bit line BL is set to 0 V, the word line WL is turned on and a voltage of the plate line PL is changed as 0V→Vcc→0V so as to write data “0”. In this case, the hysteresis of the ferroelectric capacitor C follows a course of A→B→C→D, the polarization of the ferroelectric capacitor C is reversed and the ferroelectric capacitor C turns into a state in which the data “0” is written (charge amount+Pr, position D).

When data “0” (upward polarization amount+Pr) is held in the ferroelectric capacitor C, the potential of the bit line BL is set to 0 V, the word line WL is turned on and the voltage Vcc is applied to the plate line PL so as to read the data “0”. In this case, the hysteresis of the ferroelectric capacitor C follows a course of D→C and the polarization of the ferroelectric capacitor C is not reversed. Charges flow from the ferroelectric capacitor C to the bit line BL via the transistor T, and the bit line BL is slightly charged up to have a potential V2. At this time, the reference voltage Vref is applied to the other bit line BBL. If V2<Vref, the sense amplifier circuit 15 determines that the potential of the bit line BL is “L” and the data “0” is output.

While the above description is made taking the 1T/1C cell as an example, the same thing is true for a 2T/2C cell (a memory cell that is constituted by two transistors and two capacitors, and configured so that opposing polarizations are written to the ferroelectric capacitors arranged in the memory cell to be adjacent to each other and that a polarization difference between the two capacitors is read).

Operation performed by the ferroelectric memory 10 according to this embodiment will next be described.

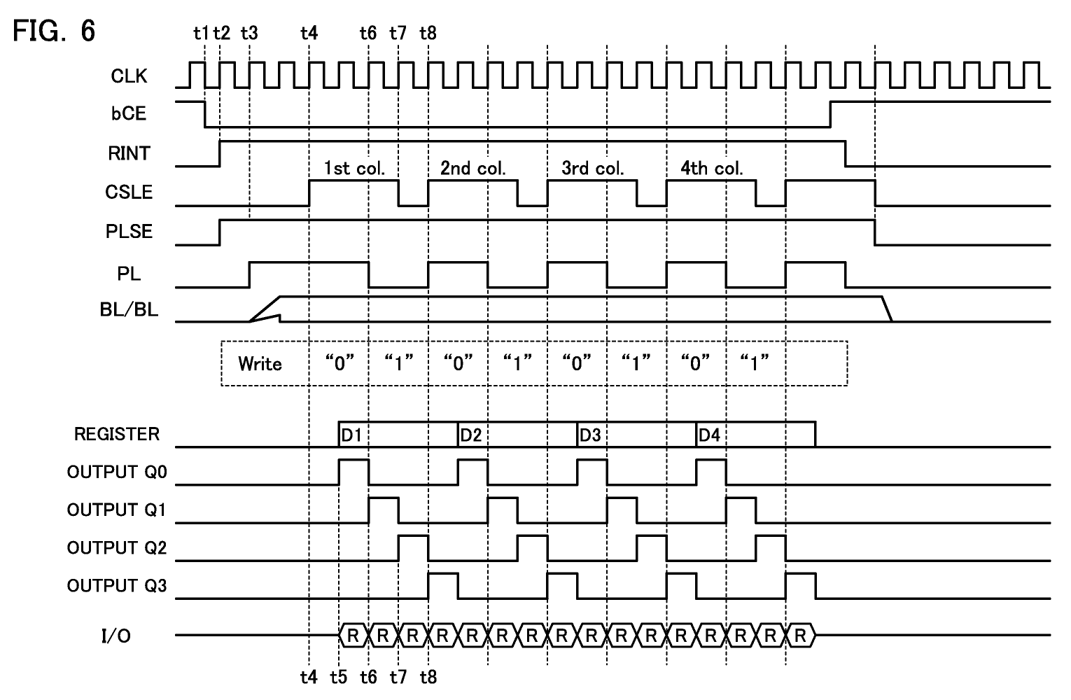

FIG. 6 is an operation timing chart of the ferroelectric memory 10. At a timing t1, a potential of the chip activation signal bCE from the data control circuit 13 becomes “L” and the chip is activated. At a timing t2, a potential of the chip internal basic signal RINT from the data control circuit 13 becomes “H”. A potential of the plate line activation signal PLSE from the address control circuit 14 becomes “H” and the NAND gate 31 of the plate line control circuit 12 is activated. At a timing t3, a potential of a plate line PL from the plate line control circuit 12 becomes “H”.

At a timing t4, a potential of the column selection signal CSLE input to the column selection line CSL from the address control circuit 14 becomes “H”, a first column is selected and the transistors QN4 and QN5 of the column gate 22 in the first column are turned on. At the same time, the reference voltage circuit 25 applies the reference voltage Vref to one of the paired bit lines BL and BBL corresponding to the selected first column and the sense amplifier circuit 15 connected to the first column is activated. Potentials of the bit lines BL and BBL are thereby compared and amplified and a data read operation is performed.

Next, during a period from the timing t4 to a timing t6 during which the potential of the plate line PL is “H”, data “0” is rewritten to the selected first column of the memory cell array 11. At the timing t6, the potential of the plate line PL becomes “L” and data “1” is rewritten to the selected first column of the memory cell array 11. At a timing t7, the potential of the column selection signal CSLE input to the column selection line CSL becomes “L” and the sense amplifier 15 connected to the first column selected so far is deactivated. The operation from the timing t4 to a timing t8 at which the column selection signal CSLE rises again is set as one cycle and operation performed on the first column that is one column of the memory cell array 11 is finished.

In this case, a data “0” rewrite time interval between the timings t4 and t6 is equal to a data “1” rewrite time interval between the timings t6 and t8. That is, the plate line control circuit 12 controls the time interval in which the potential of the plate line PL is “H” to be equal to the time interval in which the potential of the plate line PL is “L” after the first column is selected. Accordingly, the balance between the data “0” rewrite time and the data “1” rewrite time can be kept and the data reliability can be improved.

Next, at the timing t8, the potential of the column selection signal CSLE input to the column selection line CSL becomes “H” again. In response to this, the transistors QN4 and QN5 of the column gate 22 in a second column are turned on and the second column of the memory cell array 11 is selected. At the same time, the potential of the plate line PL becomes “H” and reading data from the second column of the memory cell array 11, rewriting data “0” and rewriting data “1” to the second column of the memory cell array 11 are similarly carried out.

Operation performed by the register 17 will next be described. The read data is transmitted to the register 17 (FIG. 1). At the timing t4, the data “1” read from the selected first column of the memory cell array 11 is input to the flip-flop circuit FF0 in the register region D1 of the register 17. At the timing t5, the data “1” is output to the flip-flop circuit FF1 (as an output Q0). The data “1” input to the flip-flop circuit FF1 at the timing t5 is output to the flip-flop circuit FF2 at the timing t6 (as an output Q1). The data “1” input to the flip-flop circuit FF2 at the timing t6 is output to the flip-flop circuit FF3 at the timing t7 (as an output Q2). The data “1” input to the flip-flop circuit FF3 at the timing t7 is output from the I/O terminal at the timing t8 (as an output Q3). Likewise, data read from the selected memory cells in second, third and fourth columns are shifted through the register regions D2, D3 and D4 of the register 17 and output from the I/O terminal, respectively.

As shown in FIG. 12, in the conventional ferroelectric memory, in a burst mode, after data is read out, data “0” is rewritten first and then data “1” is rewritten. Consequently, the imbalance occurs between the data “0” rewrite time and the data “1” rewrite time.

According to this embodiment, the potential of the plate line PL is changed over between “H” and “L” synchronously with the clock signal CLK. It is thereby possible to make the data “0” rewrite time equal to the data “1” rewrite time and the imbalance therebetween can be redressed. As a result, the ferroelectric memory that can suppress occurrence of such defects as the imprint to the ferroelectric capacitor, that has improved data reliability and that can read and rewrite data at high speed can be realized.

### Second Embodiment

A ferroelectric memory according to a second embodiment of the present invention will be described. The ferroelectric memory according to this embodiment is basically similar in circuit configuration to the ferroelectric memory according to the first embodiment shown in FIG. 1. However, the second embodiment differs from the first embodiment in that a data correcting operation performed by an ECC circuit 16 is added to the data read and rewrite operations described in the first embodiment. Since the data read operation and the data rewrite operation from/to the ferroelectric memory according to the second embodiment are similar to those according to the first embodiment, the description thereof will not be repeated.

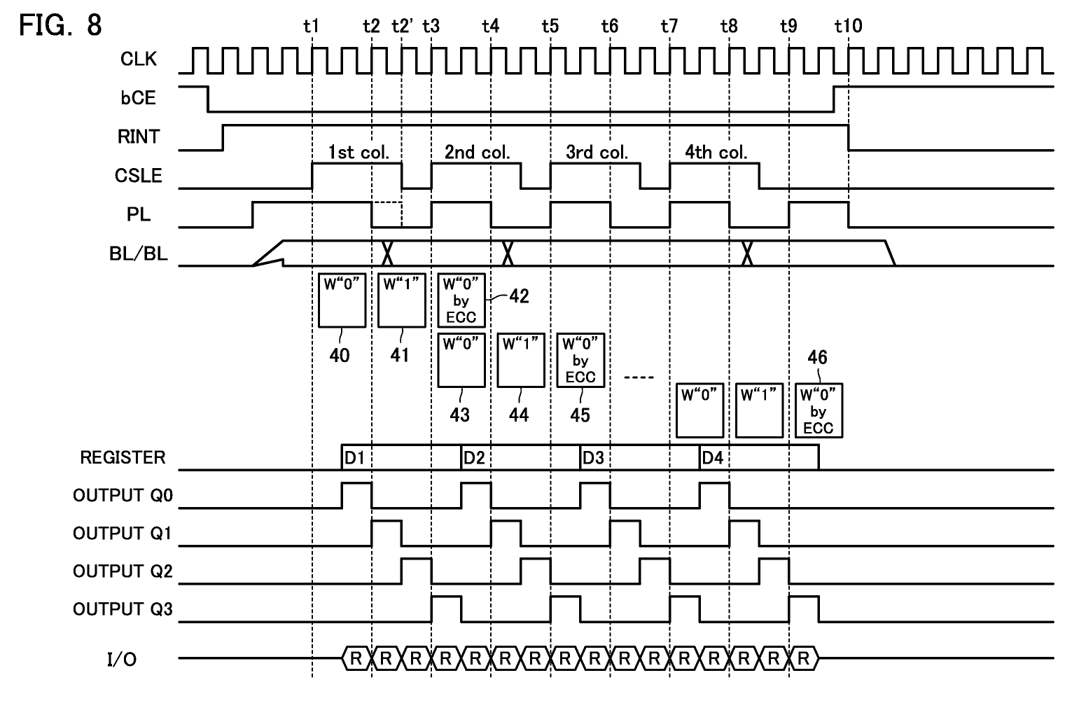

FIG. 8 is a timing chart of the data correcting operation performed by the ECC circuit 16 according to the second embodiment. At a timing t1, a potential of a column selection signal CSLE input to a column selection line CSL becomes “H”, transistors QN4 and QN5 of a column gate 22 in a first column are turned on and the first column of a memory cell array 11 is selected. Similarly to the first embodiment, a potential of a plate line PL from a plate line control circuit 12 becomes “H” in response to a plate line activation signal PLSE from an address control circuit 14, and reading data from the first column of the memory cell array 11 and rewriting data “0” are carried out (operation 40). Since the data read operation and the data rewrite operation are similar to those according to the first embodiment, the description thereof will not be repeated.

If the data read from the first column of the memory cell array 11 has errors, the ECC circuit 16 corrects the errors. An error is corrected by reversing potentials of paired bit lines BL and BBL. That is, if data “1” is to be read, the sense amplifier circuit 15 determines that the potential of the bit line BL is “L” and data “0” is output unless charges from a ferroelectric capacitor are charged on one bit line BL and the potential of the bit line BL exceeds a reference voltage Vref. This is a read error. The ECC circuit 16 detects this error and instructs a data control circuit 13 to reverse the potentials applied to the bit lines BL and BBL. In response to the instruction, the potentials applied to the bit lines BL and BBL corresponding to the selected column are reversed, the sense amplifier circuit 15 determines that the potential of the bit line BL is “H” and data “1” is output. Thereafter, rewriting of data “1” (correction) can be performed on the memory cell 11 that has erroneously output the data “0” (operation 41).

In the conventional ferroelectric memory, the potential of the plate line PL is kept “H” (between the timings t2 and t2′ indicated by dotted lines in FIG. 8) until corrected data is reflected in the bit lines. As a result, the imbalance occurs between the data “0” rewrite time (between the timings t1 and t2′) and the data “1” rewrite time (between the timings t2′ and t3). According to this embodiment, at the timing t2 prior to the timing t2′ at which the corrected data is reflected in the bit lines, the potential of the plate line PL is set to “L”. Consequently, it is possible to prevent the imbalance between the data “0” rewrite time and the data “1” rewrite time.

Here, in the operation 41, if the ECC circuit 16 corrects the data “0” to the data “1”, rewriting of the data “1” (correction) can be performed even while the potential of the plate line PL is “L”. However, if the ECC circuit 16 corrects the data “1” to the data “0”, the data “0” cannot be rewritten because the potential of the plate line PL is “L”. Therefore, rewriting of the data “0” (correction) is performed in a next cycle starting at a timing t3 at which the potential of the plate line PL becomes “H” (operation 42) in parallel to a second column read operation (operation 43).

At the timing t3, the potential of the column selection signal CSLE input to the column selection line CSL in the second column becomes “H”, the transistors QN4 and QN5 of the column gate 22 in the second column are turned on and the second column is selected. At the same time, the plate line control circuit 12 controls the potential of the plate line PL to be “H” and data “0” is read from the second column of the memory cell array 11. After reading the data “0”, data “0” is rewritten (operation 43). At a timing t4 before the corrected data is reflected in the bit lines, the potential of the plate line PL becomes “L” and rewriting of data “1” (correction) is performed on the memory cell array 11 (operation 44). Rewriting of the data “0” corrected by the ECC circuit 16 (correction) is performed at a timing t5 in a next cycle at which the potential of the plate line PL becomes “H” in parallel to a third column read cycle (operation 45).

The operations 40 to 42 are set as one cycle and the cycle of the operations is repeatedly performed on all columns of the memory cell array 11 of the ferroelectric memory 10. After rewriting of data “1” to the last column is completed, the potential of the plate line PL is set to be “H” only once to perform rewriting of the corrected data “0” (correction) (operation 46). Namely, the number of transitions of the potential of the plate line PL is larger by one than that of the potential of the column selection signal CSLE input to the column selection line CSL. However, the other operations are substantially the same.

According to this embodiment, the imbalance between the data “0” rewrite (correction) time and the data “1” rewrite (correction) time by the ECC circuit 16 can be redressed, such defects as an imprint can be prevented and data reliability of the ferroelectric memory can be improved.

### Third Embodiment

A ferroelectric memory according to a third embodiment of the present invention will be described. The ferroelectric memory according to this embodiment is basically similar in circuit configuration to the ferroelectric memory according to the first embodiment shown in FIG. 1. However, the third embodiment differs from the first embodiment in that a data control circuit 13 generates a write control signal bWE and in that an address control circuit 14 generates a column selection signal CSLE different from that according to the first embodiment. Namely, the third embodiment differs from the first embodiment in that a data write operation is appropriately performed when the write control signal bWE is “L” besides a read operation (and a rewrite operation) in a burst mode. Since the data read operation and the data rewrite operation performed by the ferroelectric memory according to this embodiment are similar to those according to the first embodiment, the description thereof will not be repeated.

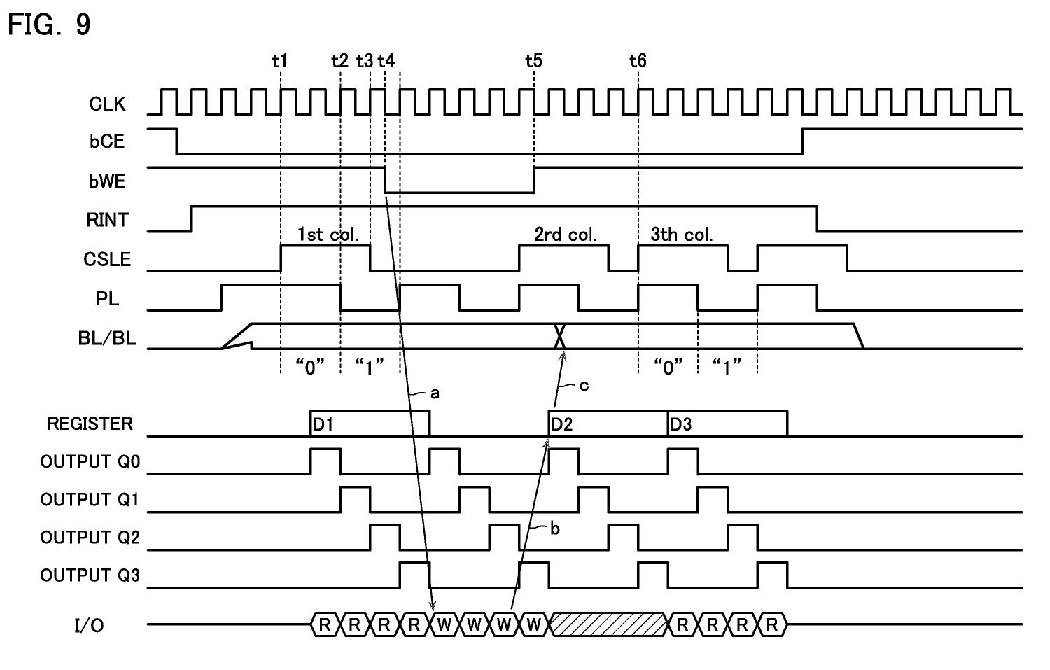

FIG. 9 is an operation timing chart according to the third embodiment. The third embodiment shows an instance in which, after reading of data, and then rewriting of data “0” and rewriting of data “1” are performed on a selected first column of a memory cell array 11, the write control signal bWE becomes “L”, then reading of data is not performed but only an ordinary data write operation is performed on a selected second column of the memory cell array 11, and in which reading of data and then rewriting of data “0” and rewriting of data “1” are performed again on a next selected third column of the memory cell array 11. Operations in this instance will be described in detail.

First, at a timing t1, a potential of the column selection signal CSLE input to a column selection line CSL becomes “H”, transistors QN4 and QN5 of a column gate 22 in the first column are turned on and the first column of the memory cell array 11 is selected. At the timing t1, as described above, a plate line control circuit 12 controls a potential of the plate line PL to be “H” in response to a plate line activation signal PSLE from the address control circuit 14, and data is read from and the data “0” is rewritten to the first column of the memory cell array 11. At a timing t2, the potential of the plate line PL becomes “L” and the data “1” is rewritten to the memory cell array 11. At a timing t3, the column selection signal CSLE input to the column selection line CSL becomes “L” and the transistors QN4 and QN5 of the column gate 22 in the first column are turned off.

Next, at a timing t4, the potential of the write control signal bWE from the data control circuit 13 becomes “L” and a sense amplifier circuit 15 of the second column is deactivated, thereby prohibiting data from being read from the second column.

Next, as indicated by an arrow ‘a’, fetching of write data starts at an I/O terminal. The write data fetched by the I/O terminal is input to a register region D2 of a register 17 as indicated by an arrow ‘b’. The write data input to the register region D2 of the register 17 is reflected in bit lines BL and BBL as indicated by an arrow ‘c’ via the data control circuit 13. Thereafter, the plate line control circuit 12 changes over the potential of the plate line PL corresponding to the second column between “H” and “L” and data is written to the second column.

At a timing t5, the potential of the write control signal bWE from the data control circuit 13 becomes “H” and a data read prohibition state is released. At a timing t6, reading of data “0” and then rewriting of data “0” are performed on the third column.

According to the third embodiment, even if the data read operation is not performed but only the data write operation is performed, the potential of the plate line PL is changed between “H” and “L” at the same time intervals. It is, therefore, possible to accelerate the data write operation and redress the imbalance between data “0” write time and data “1” write time.

### Fourth Embodiment

A ferroelectric memory according to a fourth embodiment of the present invention will be described. The ferroelectric memory according to this embodiment is basically similar in circuit configuration to the ferroelectric memory according to the first embodiment shown in FIG. 1. However, the fourth embodiment differs from the first embodiment in that a plate line control circuit 12 is configured to give a plate line signal different from that according to the first embodiment. Since a data read operation and a data rewrite operation performed by the ferroelectric memory according to this embodiment are similar to those according to the first embodiment, the description thereof will not be repeated.

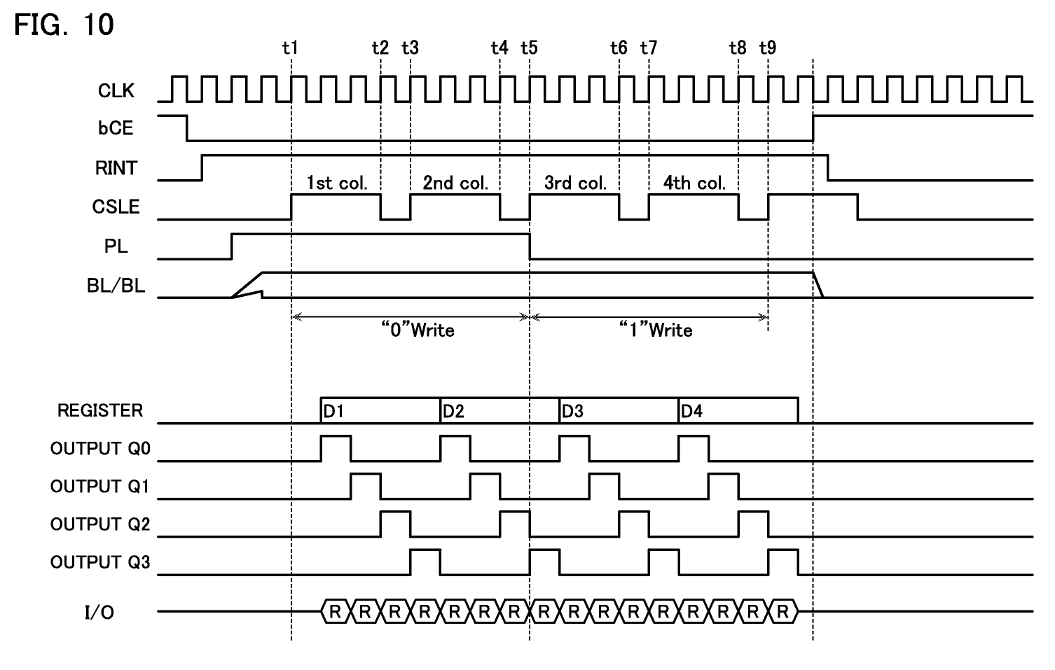

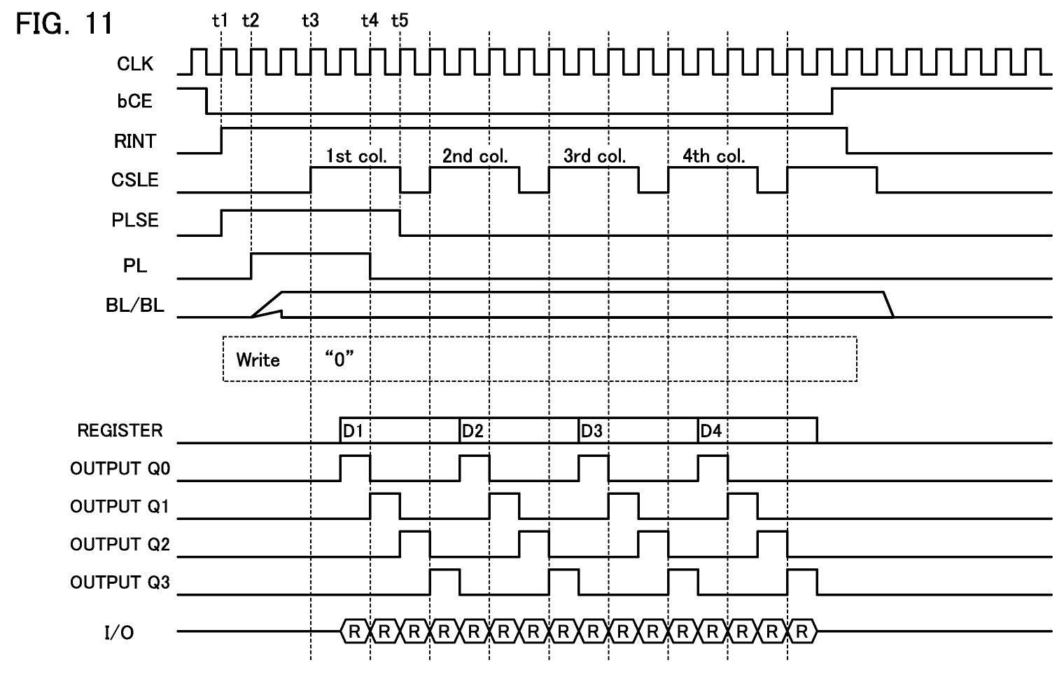

FIG. 10 is an operation timing chart according to this embodiment. The plate line control circuit 12 according to this embodiment differs from the first embodiment in that, when a data length (burst length) in which data is continuously read and written is known in advance, a potential of the plate line PL is changed such that the known burst length is equally divided into a time interval of data “0” rewrite time, and data “1” rewrite time. Operations performed by the ferroelectric memory according to this embodiment will be described below in detail with reference to the drawing.

First, at a timing t1, a column control signal CSLE input to a column selection line CSL becomes “H”, transistors QN4 and QN5 of a column gate 22 in a first column are turned on and the first column of the memory cell array 11 is selected. At a timing t2, the potential of the column control signal CSLE becomes “L”. At a timing t3, the potential of the column control signal CSLE becomes “H” again.

Between the timing t1 at which the potential of the column control signal CSLE becomes “H” and the timing t2 at which the potential of the column control signal CSLE becomes “L”, and until the timing t3 at which the column control signal CSLE becomes “H”, the plate line control circuit 12 holds the potential of the plate line PL to be “H”, and data is read from and then data “0” is rewritten to the first column of the memory cell array 11.

When the potential of the column control signal CSLE input to the column selection line CSL becomes “H” at the timing t3, the transistors QN4 and QN5 of the column gate 22 in a second column are turned on and the second column is selected. Next, at a timing t4, the potential of the column control signal CSLE becomes “L”. At a timing t5, the potential of the column control signal CSLE becomes “H” again.

Between the timing t3 at which the potential of the column control signal CSLE becomes “H” and the timing t4 at which the potential of the column control signal CSLE becomes “L”, and until the timing t5 at which the column control signal CSLE becomes “H”, the plate line control circuit 12 holds the potential of the plate line PL to be “H”, and data is read from and then data “0” is rewritten to the second column of the memory cell array 11.

At the timing t5, the plate line control circuit 12 changes over the potential of the plate line PL from “H” to “L”. At the same time, the potential of the column selection signal CSLE input to the column selection line CSL becomes “H”, the transistors QN4 and QN5 of the column gate 22 in a third column are turned on and the third column is selected. At a timing t6, the potential of the column selection signal CSLE becomes “L”. At a timing t7, the potential of the column selection signal CSLE becomes “H” again.

Between the timing t5 at which the potential of the column control signal CSLE becomes “H” and the timing t6 at which the potential of the column control signal CSLE becomes “L”, and until the timing t7 at which the column control signal CSLE becomes “H”, the plate line control circuit 12 holds the potential of the plate line PL to be “L”, and data is read from and then data “1” is rewritten to the third column of the memory cell array 11.

At the timing t7, the potential of the column selection signal CSLE input to the column selection line CSL becomes “H”, the transistors QN4 and QN5 of the column gate 22 in a fourth column are turned on and the fourth column is selected. At a timing t8, the potential of the column selection signal CSLE becomes “L”. At a timing t9, the potential of the column selection signal CSLE becomes “H” again.

Between the timing t7 at which the potential of the column control signal CSLE becomes “H” and the timing t8 at which the potential of the column control signal CSLE becomes “L”, and until the timing t9 at which the column control signal CSLE becomes “H”, the plate line control circuit 12 holds the potential of the plate line PL to be “L”, and data is read from and then data “1” is rewritten to the fourth column of the memory cell array 11.

According to this embodiment, a time interval is divided into a time interval in which the potential of the plate line PL is “H” and a time interval in which the potential of the plate line PL is “L” substantially equally. Consequently, the imbalance between data “0” rewrite time and data “1” rewrite time can be redressed. At the same time, power consumption can be suppressed by decreasing the number of transitions of the potential of the plate line PL.

### Fifth Embodiment

A ferroelectric memory according to a fifth embodiment of the present invention will be described. The ferroelectric memory according to this embodiment is basically similar in circuit configuration to the ferroelectric memory according to the first embodiment shown in FIG. 1. However, the fifth embodiment differs from the first embodiment in that a plate line control circuit 12 is configured to give a plate line signal different from that according to the first embodiment. Since a data read operation and a data rewrite operation performed by the ferroelectric memory are similar to those according to the first embodiment, the description thereof will not be repeated.

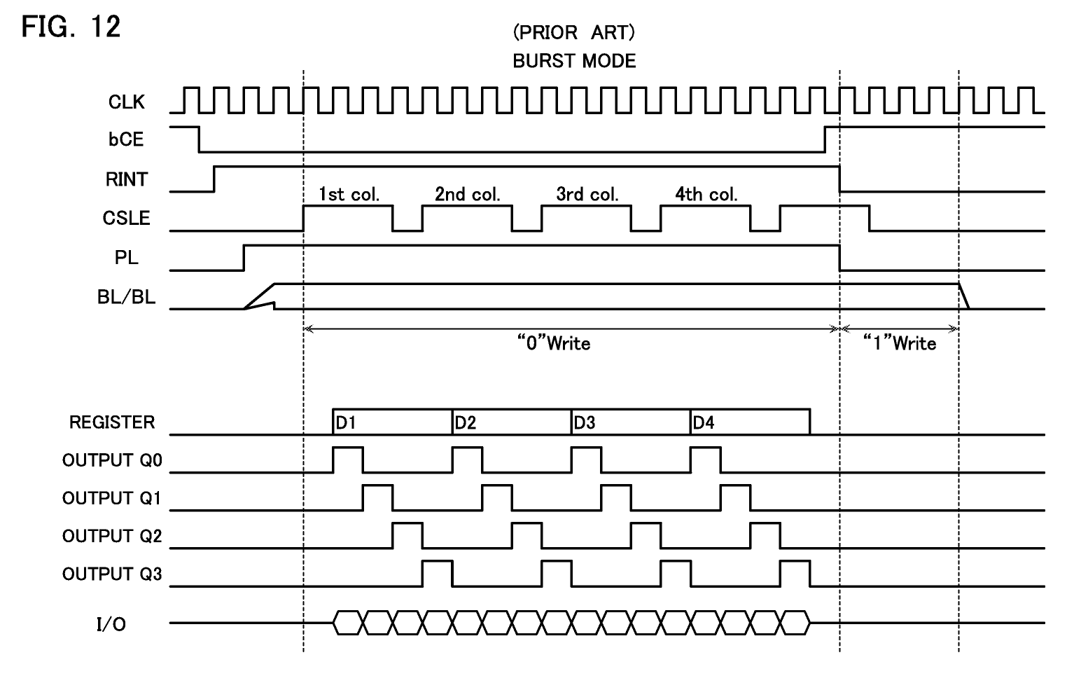

In this embodiment, in a burst mode, a potential of the plate line PL is set “H” only at the beginning of an operation cycle. By doing so, data is read from and data “0” is rewritten to all columns and thereafter the potential of the plate line PL is held to be “L”. Operations performed by the ferroelectric memory according to this embodiment will be described in detail with reference to the drawing. FIG. 11 is an operation timing chart according to this embodiment.

First, at a timing t1, a plate line activation signal PLSE from an address control circuit 14 becomes “H” synchronously with a clock signal CLK. At a timing t2, the potential of the plate line PL output from the plate line control circuit 12 becomes “H”. At a timing t3, a column control signal CSLE input to a column selection line CSL becomes “H”, transistors QN4 and QN5 of a column gate 22 in a first column are turned on and the first column is selected. In the example shown in FIG. 11, only the first column is selected. Alternatively, all the columns may be selected simultaneously. The plate line control circuit 12 holds the potential of the plate line PL to be “H” before a timing t4. The potential of the plate line PL becomes “L” at the timing t4, and is held to be “L” thereafter. Between the timings t3 and t4, data is read from and then data “0” is rewritten to the first column (or all the columns) of the memory cell array 11. Next, at a timing t5, the potential of the plate line activation signal PLSE from the address control circuit 14 becomes “L” and, at the same time, the potential of the column control signal CSLE becomes “L”.

According to this embodiment, at the beginning of a circuit operation, the potential of the plate line PL is changed from “H” to “L” only once and data is read from and the data “0” is rewritten to all the columns. Consequently, even if an accident (such as an electric power failure) occurs, data is not lost or not changed and data reliability of the ferroelectric memory can be improved. Furthermore, power consumption of the ferroelectric memory can be suppressed.

[Other Modifications]

The embodiments of the present invention have been described. However, the present invention is not limited to these embodiments but various modifications, additions and the like can be made without departing from the spirit of the present invention. For example, in the embodiments, the ferroelectric memory having the 1T/1C memory cell structure has been described. However, the present invention can be similarly applied to a ferroelectric memory having a 2T/2C memory cell structure. Moreover, the present invention can be similarly applied to a series-connected TC parallel unit ferroelectric memory configured so that a plurality of 1T/1C memory cells is connected in series in a cascade arrangement (see, for example, FIG. 9 of Japanese Patent Application Laid-Open No. 2001-250376).

What is claimed is:

1. A semiconductor memory device comprising:
a memory cell array comprising a ferroelectric capacitor;
a selection transistor configured to select a column of the memory cell array and to connect the selected column to a bit line;
a plate line configured to apply a potential for reading or writing data from or to the ferroelectric capacitor;
a sense amplifier circuit configured to compare and amplify a signal read from the ferroelectric capacitor to the bit line; and
a plate line control circuit configured to control a potential of the plate line synchronously with a clock signal.

2. The semiconductor memory device of claim 1,
wherein the plate line control circuit comprises a frequency divider circuit configured to generate a frequency dividing signal synchronously with the clock signal, the frequency dividing signal comprising a cycle of an integer multiple of a cycle of the clock signal.

3. The semiconductor memory device of claim 1, wherein the plate line control signal comprises:
a frequency divider circuit configured to generate a frequency dividing signal synchronously with the clock signal, the frequency dividing signal comprising a cycle of an integer multiple of a cycle of the clock signal;
a NAND gate configured to receive the frequency dividing signal and a plate line activation signal as inputs, the NAND gate performing an AND operation between the frequency dividing signal and the plate line activation signal and outputting an AND signal; and
an inverter configured to invert the AND signal and to output an inverted signal of the AND signal to the plate line.

4. The semiconductor memory device of claim 1, further comprising an error correction and checking (ECC) circuit configured to correct an error of a signal output from the sense amplifier circuit if the signal comprises the error,
wherein data corrected by the ECC circuit is written back in a next cycle comprising switching of the potential of the plate line between a first potential and a second potential.

5. The semiconductor memory device of claim 4,
wherein the memory cell array comprises a parity area configured to hold parity data for error correction, and
the ECC circuit is configured to correct the error using the parity data read from the parity area.

6. The semiconductor memory device of claim 1,
wherein the plate line control circuit is configured to control the potential of the plate line synchronously with the clock signal in such a manner that a time interval while the potential of the plate line is a first potential is substantially equal to a time interval while the potential of the plate line is a second potential.

7. The semiconductor memory device of claim 6,
wherein the plate line control circuit is configured to switch over the potential of the plate line between the first potential and the second potential synchronously with the clock signal while at least one column is selected.

8. The semiconductor memory device of claim 6, wherein the plate line control circuit comprises a frequency divider circuit generating a frequency dividing signal synchronously with the clock signal, the frequency dividing signal comprising a cycle of an integer multiple of a cycle of the clock signal.

9. The semiconductor memory device of claim 6, further comprising an error correction and checking (ECC) circuit configured to correct an error of a signal output from the sense amplifier circuit if the signal comprises the error,
wherein data corrected by the ECC circuit is written back in a next cycle comprising switching of the potential of the plate line between a first potential and a second potential.

10. The semiconductor memory device of claim 9,
wherein the plate line control circuit comprises a frequency divider circuit configured to generate a frequency dividing signal synchronously with the clock signal, the frequency dividing signal comprising a cycle of an integer multiple of a cycle of the clock signal.

11. The semiconductor memory device of claim 9,
wherein the plate line control signal comprises a frequency divider circuit configured to generate a frequency dividing signal synchronously with the clock signal, the frequency dividing signal comprising a cycle of an integer multiple of a cycle of the clock signal;
a NAND gate configured to receive the frequency dividing signal and a plate line activation signal as inputs, the NAND gate performing an AND operation between the frequency dividing signal and the plate line activation signal and outputting an AND signal; and
an inverter configured to invert the AND signal and to output an inverted signal of the AND signal to the plate line.

12. The semiconductor memory device of claim 9,
wherein the memory cell array comprises a parity area configured to hold parity data for error correction, and
the ECC circuit is configured to correct the error using the parity data read from the parity area.

13. The semiconductor memory device of claim 1, further comprising:
an error correction and checking (ECC) circuit configured to correct an error of a signal output from the sense amplifier circuit if the signal comprises the error;
a column gate configured to selectively connect the bit line to a data line; and
an address control circuit configured to output a column selection signal in order to select the column gate,
wherein the ECC circuit is configured to correct data read from a first column and to read data from a second column selected next to the first column by the address control circuit in parallel.

14. The semiconductor memory device of claim 13,
wherein the memory cell array comprises a parity area configured to hold parity data for error correction, and
the ECC circuit is configured to correct the error using the parity data read from the parity area.

15. The semiconductor memory device of claim 14, wherein the plate line control circuit is configured to control the potential of the plate line such that a time interval for reading or writing the data is divided into:
a first time interval in which the potential of the plate line is kept to a first potential; and
a second time interval in which the potential of the plate line is kept to a second potential,
when a burst mode of continuously reading or writing data is selected and a data length of the continuously read or written data is known.

16. The semiconductor memory device of claim 15,
wherein the memory cell array comprises a parity area configured to hold parity data for error correction, and
the ECC circuit is configured to correct the error using the parity data read from the parity area.
